(19) United States
(12) Patent Application Publication
(10) Pub. No.: US 2006/0011928 A1
(43) Pub. Date: Jan. 19, 2006

(54) Surface-mountable light-emitting diode and/or photodiode and method for the production thereof

(75) Inventors: Jorg Sorg, Regensburg (DE); Georg Bogner, Lappersdorf (DE); Gunter Waitl, Regensburg (DE); Reinhold Brunner, Zell (DE)

Correspondence Address: COHEN, PONTANI, LIEBERMAN & PAVANE, 551 FIFTH AVENUE, SUITE 1210, NEW YORK, NY, 10176, US

(73) Assignee: Osram Opto Semiconductors GmbH, Regensburg (DE)

(21) Appl. No.: 10/519,347

(22) PCT Filed: Jun. 4, 2003
(86) PCT No.: PCT/DE03/01831

§ 371 Date: Jun. 20, 2005

(30) Foreign Application Priority Data
Jun. 26, 2002 (DE) 102 28 634.5

(51) Int. Cl. H01L 31/0203; H01L 33/00; H01L 31/0232

(52) U.S. Cl. 257/81; 257/433; 257/432; 257/99

(57) ABSTRACT

A surface-mountable miniature luminescent diode with a chip package which has a leadframe (16) and a semiconductor chip (22) which is arranged on the leadframe (16) and is in electrical contact with it and which contains an active, radiation-emitting region. The leadframe (16) is formed by a flexible multi-layered sheet (12, 14).

The invention relates to a surface-mountable miniature luminescent diode and/or photodiode with a chip package which has a leadframe and a semiconductor chip which is arranged on the leadframe and is in electrical contact with it and which contains an active, radiation-emitting region. The invention also relates to a method for producing a luminescent diode of this type.

To extend the areas of use and to reduce the production costs, it is attempted to produce luminescent diodes and/or photodiodes in ever smaller overall sizes. Very small luminescent diodes are required for example for the background illumination of the buttons of cell phones.

In the meantime, LED packages with a footprint specified as 0402 (corresponding to 0.5 mm×1.0 mm) and a component height of 400 μm-600 μm are available. However, a further reduction of the component height proves to be difficult with the current package concepts.

The present invention is based on the object of providing a surface-mountable miniature luminescent diode and/or photodiode of the type stated at the beginning which allows further reduction of its overall size.

This object is achieved by a surface-mountable miniature luminescent diode and/or photodiode with the features of claim 1 and the method for producing a surface-mountable luminescent diode and/or photodiode with the features of claim 12. Advantageous developments and refinements of the invention emerge from the subclaims.

According to the invention, it is provided in the case of a surface-mountable miniature luminescent diode and/or photodiode of the generic type that the leadframe is formed by a flexible multi-layered sheet. The invention is therefore based on the idea of creating a luminescent diode and/or photodiode of a small footprint which can be produced with a high packing density, and consequently with low production costs, by mounting the radiation-generating and/or radiation-receiving semiconductor chip on a flexible leadframe.

In a preferred refinement of the invention, it is provided that the flexible multi-layered sheet comprises a metal foil and a plastic film arranged on the metal foil and connected to it.

In this case, it is expedient for the plastic film to be adhesively bonded to the metal foil. The film and the foil connected to each other consequently represent a flexible leadframe for the semiconductor chip.

It is preferred in this context if the metal foil comprises a first chip connection region and a second chip connection region, and the plastic film has openings in the regions that are arranged on these chip connection regions. The semiconductor chip can then advantageously be arranged with a first contact area on the first chip connection region, and be connected with a second contact area in an electrically conducting manner to the second chip connection region, for example by means of a bonding wire. This means that the semiconductor chip is mounted on the first chip connection region through a first clearance and the electrical connection of the second contact area to the second chip connection region is established through a second clearance.

In a preferred refinement of the invention, the thickness of the metal foil is less than 80 μm, and is preferably between 30 μm and 60 μm inclusive. Such a small metallization thickness allows the realization of a very low package height of less than 400 μm, in particular of less than 350 μm. This overall height can also be advantageously realized with a chip height of 150 μm, without at the same time the arc of a bonding wire between the second contact area of the chip and the second chip connection region having to be made much smaller. It goes without saying that, with the present form of construction, particularly low overall heights can be achieved even with conventionally standard chip thicknesses of between 220 μm and 250 μm.

In a preferred embodiment, the plastic film is formed by an epoxy resin film. In this context, it is further preferred if the plastic film has a thickness of less than 80 μm, preferably a thickness of between 30 μm and 60 μm inclusive.

In an expedient development of the invention it is provided that the semiconductor chip is embedded in a transparent or translucent injection-molding composition. Instead of the injection-molding composition, a transfer-moulding composition may be used.

The invention offers particularly great advantages for miniature luminescent diodes in which the leadframe has dimensions of approximately 0.5 mm×1.0 mm or less, in particular in the case of luminescent diodes which have a component height of approximately 400 μm or less, preferably of approximately 350 μm or less.

Apart from the stated advantages, luminescent diodes of the type described above offer a low thermal resistance Rₜₕ, so that a high power dissipation is possible on account of the good heat removal. The described construction also allows very flexible designs with a plurality of chips (multichip designs) to be realized in a confined space.

According to the invention, the method for producing a surface-mountable luminescent diode comprises the method steps of:
providing a leadframe which is a flexible multi-layered sheet which has at least one first chip connection region and at least one second chip connection region;
providing at least one semiconductor chip, which contains an active, radiation-emitting and/or radiation-receiving region and has a first contact area and a second contact area;
mounting the semiconductor chip with the first contact area on the first chip connection region of the leadframe;
connecting the second contact area to the second chip connection region of the leadframe; and
producing an encapsulation for the semiconductor chip by casting, injection-molding, transfer-molding extruding or extrusion coating (referred to hereafter collectively as “encapsulating”) the semiconductor chip with encapsulating material, which is permeable to the emitted and/or received radiation, in particular with correspondingly transparent or translucent polymer material.

In a preferred refinement, the step of providing a leadframe comprises providing and punching a thin metal foil in order to define the first and second chip connection regions.

In a further expedient refinement, the step of providing a leadframe comprises providing and punching a thin plastic film in order to define openings for the electrical connection of the semiconductor chip.

The foil and the film are then advantageously adhesively bonded to each other in the step of providing a leadframe.

In the above context, it is also expedient if, in the encapsulating step, the encapsulating material is injection-molded, transfer-molded or sprayed onto the plastic film of the multi-layered sheet. This ensures good bonding of the encapsulating body to the flexible leadframe.

Furthermore, in the encapsulating step, a runner is advantageously led through a plurality of devices arranged on the multi-layered sheet. As a result, the number of runners is reduced in comparison with the standard procedure of feeding polymer to each component through a single runner, so that a large number of components can be realized in a confined space.

In a preferred form of the method according to the invention, the first and second chip connection regions of the leadframe are short-circuited and grounded in the steps of mounting the semiconductor chip, connecting the second contact area and encapsulating the semiconductor chip. As a result, static charges are prevented and damage to the components caused by electrostatic discharges (ESD) is avoided.

It is also preferred in the case of the method according to the invention if a plurality of devices arranged on the multi-layered sheet are tested for their functional capability after the encapsulating step. For this purpose, the individual devices are electrically isolated when they are mounted.

The use of the flexible leadframe material allows all the process steps of the method according to the invention to be carried out reel-to-reel (from a payoff reel to a takeup reel), which minimizes the handling effort in production.

In addition, with the concept described there is the possibility of dispensing with the taping of the components. If desired, a plurality of components that belong together can, after a chip test, be delivered on the flexible frame together with a wafer map. Alternatively, after the chip test, the components can be singularized, taped and delivered.

Further advantageous refinements, features and details of the invention emerge from the dependent claims, the description of the exemplary embodiment and the drawings.

Further advantages, developments and refinements of the miniature luminescent diode and/or photodiode according to the invention emerge from the exemplary embodiment explained below in conjunction with the drawing. Only the elements that are essential for understanding the invention are respectively represented in the drawing, in which:

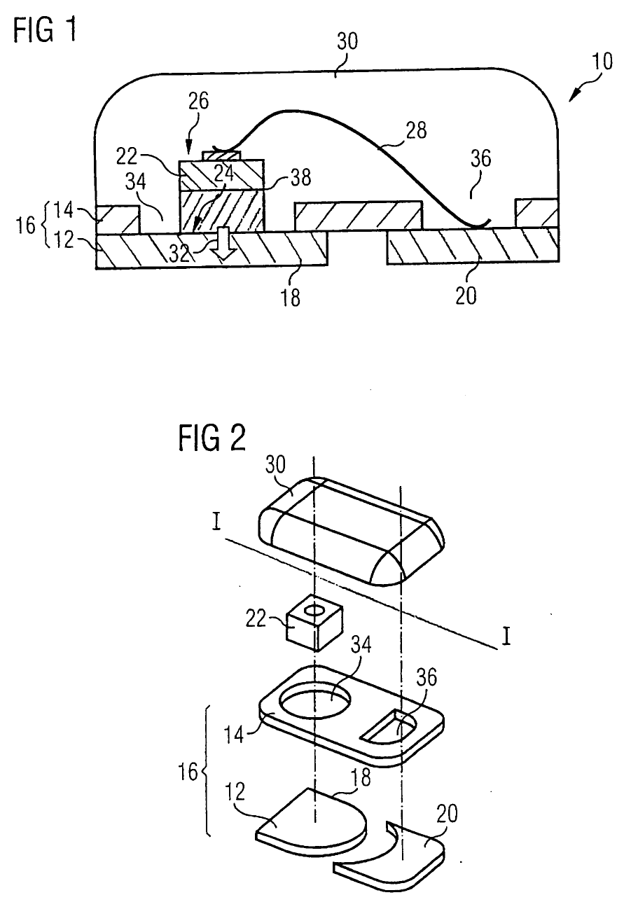

FIG. 1 shows a schematic sectional view of the exemplary embodiment; and

FIG. 2 shows a perspective view of the exemplary embodiment from FIG. 1 in an exploded representation.

FIGS. 1 and 2 show in a schematic representation a surface-mountable miniature luminescent diode which is designated generally by 10.

The miniature luminescent diode 10 has a flexible leadframe 16, an LED chip 22 with an active, radiation-emitting region 38 and an encapsulating body 30. The flexible leadframe 16 in this case comprises a 60 μm thick metal foil 12 and a likewise 60 μm thick epoxy resin film 14, which are adhesively bonded to each other extremely precisely.

The metal foil 12 is punched in such a way that it defines a cathode 18 and an anode 20. Openings 34 and 36 are respectively punched in the plastic film 14 above the cathode and the anode. The LED chip 22 is bonded by its underside 24 onto the cathode 18 through the clearance 34. The anode 20 is connected to the upper side 26 of the LED chip 22 through the clearance 36 by means of a bonding wire 28.

To be able to realize as many components as possible on the flexible frame, what is known as cavity-to-cavity molding is used for example for the encapsulation. In this way, the number of runners is reduced by leading a runner through the components.

Lost heat generated during the operation of the luminescent diode is effectively dissipated by the metal foil 12 (reference numeral 32).

Altogether, the miniature luminescent diode 10 has a footprint of approximately 0.5 mm×1.0 mm and has a total component height of only 350 μm.

The features of the invention that are disclosed in the description above, in the drawing and in the claims may be essential for realizing the invention both individually and in any desired combination. Instead of the luminescent diode chip, a photodiode chip may be used, or a chip which is operated as a luminescent diode and as a photodiode.

1. A surface-mountable miniature luminescent diode and/or photodiode with a chip package which has a leadframe (16), and
a semiconductor chip (22) which is arranged on the leadframe (16) and is in electrical contact with it and which contains an active, radiation-emitting and/or radiation-receiving region,
wherein the leadframe (16) is formed by a flexible multi-layered sheet (12, 14).

2. The surface-mountable miniature luminescent diode and/or photodiode as claimed in claim 1, wherein the flexible multi-layered sheet (12, 14) comprises a metal foil (12) and a plastic film (14) arranged on the metal foil and connected to it.

3. The surface-mountable miniature luminescent diode and/or photodiode as claimed in claim 2, wherein the plastic film (14) is adhesively bonded to the metal foil (12).

4. The surface-mountable miniature luminescent diode and/or photodiode as claimed in claim 2, wherein the metal foil (12) comprises a first chip connection region (18) and a second chip connection region (20), and in that the plastic film has openings (34, 36) in the regions arranged on these chip connection regions (18, 20).

5. The surface-mountable miniature luminescent diode and/or photodiode as claimed in claim 4, wherein the semiconductor chip (22) comprises a first contact area (24) on the first chip connection region (18), and a second contact area (26) coupled to the second chip connection region (20).

6. The surface-mountable miniature luminescent diode and/or photodiode as claimed in claim 2, wherein the thickness of the metal foil (12) is less than 80 μm, in particular between 30 μm and 60 μm inclusive.

7. The surface-mountable miniature luminescent diode and/or photodiode as claimed in claim 2, wherein the plastic film comprises an epoxy resin film (14).

8. The surface-mountable miniature luminescent diode and/or photodiode as claimed in claim 2, wherein the thickness of the plastic film (14) is less than 80 μm, in particular between 30 μm and 60 μm inclusive.

9. The surface-mountable miniature luminescent diode and/or photodiode as claimed in claim 1, wherein the semiconductor chip (22) is embedded in an encapsulating material (30).

10. The surface-mountable miniature luminescent diode and/or photodiode as claimed in claim 1, wherein the leadframe (16) has footprint dimensions of approximately 0.5 mm×1.0 mm or less.

11. The surface-mountable miniature luminescent diode and/or photodiode as claimed in claim 1, wherein the luminescent diode (10) has a total thickness of approximately 400 μm or less, preferably of approximately 350 μm or less.

12. A method for producing a surface-mountable miniature luminescent diode and/or photodiode, comprising:
providing a leadframe from a flexible multi-layered sheet which has a first chip connection region and a second chip connection region;
providing a semiconductor chip, which contains an active, radiation-emitting region and has a first contact area and a second contact area;
mounting the semiconductor chip with the first contact area on the first chip connection region of the leadframe;
connecting the second contact area to the second chip connection region of the leadframe; and
encapsulating the semiconductor chip with a transparent or translucent encapsulating material.

13. The method as claimed in claim 12, wherein the step of providing a leadframe comprises providing and punching a thin metal foil in order to define the first and second chip connection regions.

14. The method as claimed in claim 13, wherein the step of providing a leadframe comprises providing and punching a thin plastic film in order to define openings for the electrical connection of the semiconductor chip.

15. The method as claimed in claim 14, wherein the step of providing a leadframe comprises the adhesive bonding of the foil and the film.

16. The method as claimed in claim 12. wherein, in the encapsulating step, the encapsulating material is injection-molded, transfer-molded or sprayed onto the plastic film of the multi-layered sheet

17. The method as claimed in claim 12, wherein, in the encapsulating step, a runner is led through a plurality of chips arranged on the multi-layered sheet.

18. The method as claimed in claim 12, wherein the first and second chip connection regions of the leadframe are short-circuited and grounded in the steps of mounting the semiconductor chip, connecting the second contact area and encapsulating the semiconductor chip.

19. The method as claimed in claim 12, wherein a plurality of chips arranged on the multi-layered sheet are tested for their functional capability after the encapsulating step and in that, for this purpose, the individual chips are electrically isolated when they are mounted.
